(19) United States
(12) Patent Application Publication
(10) Pub. No.: US 2007/0063255 A1
(43) Pub. Date: Mar. 22, 2007

(54) Non-volatile memory device and method of manufacturing the same

(75) Inventors: Jae-Young Ahn, Seongnam-si (KR); Ki-Hyan Hwang, Seongnam-si (KR); Jin-Tae Noh, Suwon-si (KR); Hong-Suk Kim, Yongin-si (KR); Sung-Hae Lee, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/492,733

(22) Filed: Jul. 25, 2006

(30) Foreign Application Priority Data
Jul. 27, 2005 (KR) 10-2005-68303

(51) Int. Cl. H01L 21/336; H01L 29/788

(52) U.S. Cl. 257/315; 438/257; 438/258

(57) ABSTRACT

In non-volatile memory devices and methods of manufacturing the non-volatile memory devices, a barrier layer having an upper portion of silicon nitride and a lower portion of silicon oxide is formed on a substrate by providing a silicon oxide layer on the substrate and performing a radical nitridation process on an upper portion of the silicon oxide layer. A trapping layer including silicon nitride is formed on the barrier layer. A blocking layer and a gate electrode layer are subsequently formed on the trapping layer. The gate electrode layer, the blocking layer, the trapping layer and the barrier layer are then partially etched to provide a gate structure.

### CROSS REFERENCE TO RELATED APPLICATION

This application claims priority to Korean Patent Application No. 2005-0068303 filed on Jul. 27, 2005, the contents of which are incorporated herein by reference in their entirety.

### BACKGROUND OF THE INVENTION

1. Field of the Invention

The present invention relates to non-volatile memory devices and methods of manufacturing the non-volatile memory devices. More particularly, the present invention relates to non-volatile memory devices that retain data even though power is removed and methods of manufacturing the same.

2. Description of the Related Art

In general, semiconductor memory devices can be classified as either a volatile memory device or a non-volatile memory device. Examples of volatile memory devices include dynamic random access memory (DRAM) devices and static random access memory (SRAM) devices. The data input speed and data output speed of the volatile memory device are relatively fast. However, data that are stored in the non-volatile memory device are not retained when power is removed.

An example of a non-volatile memory device is a read only memory (ROM) device such as an electrically erasable programmable read only memory (EEPROM) device. Recently, flash memory devices, a type of EEPROM device, have enjoyed widespread use. Data input speed and data output speed of a flash memory device are relatively slow. However, a flash memory device can retain its data even though power is removed.

In order to program and/or erase data, the flash memory device can employ Fowler-Nordheim tunneling or hot electron injection. In addition, flash memory devices can generally be classified as either a floating gate type flash memory device or a silicon-oxide-nitride-oxide-semiconductor (SONOS) type flash memory device.

The SONOS type flash memory device employs a bi-layer including a first silicon nitride pattern and a second silicon nitride pattern in order to improve carrier retention characteristics. The first silicon nitride pattern and the second silicon nitride pattern can be subsequently formed on a tunnel oxide layer pattern. However, when the bi-layer is employed in the SONOS type flash memory device, an interface is present between the first silicon nitride pattern and the second silicon nitride pattern. In addition, it is difficult to control the thicknesses of the first and second silicon nitride patterns. It is further difficult to enable the first silicon nitride layer and the second silicon nitride layer to have a relatively small trap density and a relatively large trap density, respectively. Each of these limitations can result in reduced reliability in the SONOS type flash memory device.

### SUMMARY OF THE INVENTION

The present invention provides non-volatile memory devices and methods for manufacturing such devices, that address and overcome the limitations of conventional approaches described above, leading to improved reliability.

In one aspect, the present invention is directed to a non-volatile memory device having a substrate, a barrier layer pattern, a trapping layer pattern, a blocking layer pattern, and a gate electrode pattern. The substrate has a channel region. The barrier layer pattern is on the channel region of the substrate. The barrier layer pattern has an upper portion including silicon nitride and a lower portion including silicon oxide. The barrier layer pattern is formed by providing a silicon oxide layer on the substrate and performing a radical nitridation process on an upper portion of the silicon oxide layer. The trapping layer pattern is on the barrier layer pattern. The trapping layer pattern includes silicon nitride. The blocking layer pattern is on the trapping layer pattern. The gate electrode layer pattern is on the blocking layer pattern.

In one embodiment, no interface is present between the upper portion and the lower portion of the barrier layer pattern.

In another embodiment, the formation of the barrier layer pattern further comprises partially etching the silicon oxide layer after performing the radical nitridation process on the upper portion of the silicon oxide layer.

In another embodiment, the radical nitridation process uses a reaction gas including ammonia.

In another embodiment, the reaction gas further includes at least one material selected from the group consisting of tetrachlorosilane and dichlorosilane.

In another aspect, the present invention is directed to a method of manufacturing a non-volatile memory device. A silicon oxide layer is formed on a substrate. A barrier layer is formed by performing a radical nitridation process on an upper portion of the silicon oxide layer. The barrier layer has an upper portion including silicon nitride and a lower portion including silicon oxide. A trapping layer is formed on the barrier layer. The trapping layer includes silicon nitride. A blocking layer is formed on the trapping layer. A gate electrode layer is formed on the blocking layer. The gate electrode layer, the blocking layer, the trapping layer and the barrier layer are partially etched.

In one embodiment, the method further comprises partially etching the upper portion of the barrier layer.

In another embodiment, no interface is present between the upper portion and the lower portion of the barrier layer pattern.

In another embodiment, the silicon oxide layer is formed on the substrate by a radical oxidation process.

In another embodiment, the radical nitridation process uses a reaction gas including ammonia.

In another embodiment, the reaction gas further includes at least one material selected from the group consisting of tetrachlorosilane and dichlorosilane.

In another embodiment, the trapping layer is formed on the barrier layer by using a reaction gas including at least one material selected from the group consisting of hexachlorodisilane, trisilane and octachlorotrisilane.

In another embodiment, the trapping layer is formed on the barrier layer at a temperature of about 450° C. to about 650° C.

### BRIEF DESCRIPTION OF THE DRAWINGS

The above and other advantages of the present invention will become readily apparent by reference to the following detailed description when considered in conjunction with the accompanying drawings in which:

FIG. 1 is a cross-sectional view illustrating non-volatile memory devices in accordance with some embodiments of the present invention; and

FIGS. 2 to 6 are cross-sectional views illustrating methods of manufacturing the memory devices of FIG. 1.

### DETAILED DESCRIPTION OF EMBODIMENTS OF THE INVENTION

Embodiments of the present invention will be described with reference to the accompanying drawings. The present invention may, however, be embodied in many different forms and should not be construed as limited to the embodiments set forth herein. Rather, the embodiments are provided so that disclosure of the present invention will be thorough and complete. The principles and features of this invention can be employed in varied and numerous embodiments without departing from the scope of the present invention. In the drawings, the size and relative sizes of layers and regions may be exaggerated for clarity. The drawings are not necessarily to scale. Like reference numerals refer to like elements throughout.

It will be understood that when an element or layer is referred to as being “on”, “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Embodiments of the present invention are described with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature of a device and are not intended to limit the scope of the present invention.

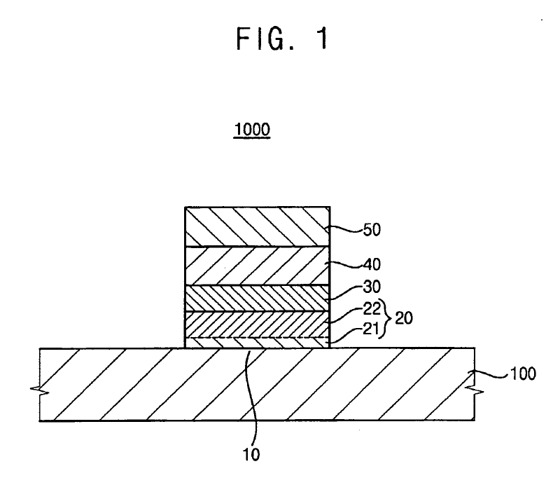

FIG. 1 is a cross-sectional view illustrating non-volatile memory devices in accordance with some embodiments of the present invention.

Referring to FIG. 1, a non-volatile memory device 1000 includes a substrate 100, a barrier layer pattern 20, a trapping layer pattern 30, a blocking layer pattern 40 and a gate electrode layer pattern 50. The substrate 100 has a channel region 10.

Particularly, the barrier layer pattern 20 is provided on the channel region 10 of the substrate 100. The barrier layer pattern 20 is operative as an energy barrier. The barrier layer pattern 20 has a lower portion 21 and an upper portion 22. The lower portion 21 and the upper portion 22 can comprise silicon oxide and silicon nitride, respectively.

In order to form the barrier layer pattern 20, a silicon oxide layer is formed on the substrate 100. A radical nitridation process using a reaction gas including ammonia (NH₃) is then performed on an upper portion of the silicon oxide layer. Thereafter, the silicon oxide layer is partially etched so that the barrier layer pattern 20 is formed. In this manner, an interface may not be present between the lower portion 21 and the upper portion 22 of the barrier layer pattern 20.

When the thickness of the lower portion 21 of the barrier layer pattern 20 is less than about 15 Å, this is disadvantageous in that the resulting barrier layer pattern 20 may not efficiently serve as an energy barrier. On the other hand, when the thickness of the lower portion 21 of the barrier layer pattern 20 is greater than about 50 Å, this can cause the operation voltage of the resulting non-volatile memory device 1000 to increase. Thus, the thickness of the lower portion 21 is preferably in a range of about 15 Å to about 50 Å.

Since the upper portion 22 of the barrier layer pattern 20 is formed by the radical nitridation process, the upper portion 22 may have a relatively dense structure. In addition, the number of silicon-silicon bonds in the upper portion 22 of the barrier layer pattern 20 may be relatively small. Thus, the upper portion 22 of the barrier layer pattern 20 may have a relatively small trap density.

When the thickness of the upper portion 22 of the barrier layer pattern 20 is less than about 10 Å, this is disadvantageous in that the barrier layer pattern 20 may not efficiently serve as an energy barrier. On the other hand, when the thickness of the upper portion 20 is greater than about 200 Å, this can cause the operation voltage of the non-volatile memory device 1000 to increase. Thus, the thickness of the upper portion 22 is preferably in a range of about 10 Å to about 200 Å.

The trapping layer pattern 30 is provided on the barrier layer pattern 20. The trapping layer pattern 30 comprises, for example, silicon nitride. In one embodiment, the trapping layer pattern 30 is formed using a silicon source gas and a nitrogen source gas by a chemical vapor deposition (CVD) process or an atomic layer deposition (ALD) process. The silicon source gas comprises, for example, hexachlorodisilane (HCS: Si₂Cl₆), trisilane (Si₃H₈), octachlorotrisilane (Si₃Cl₈), or a combination (or a mixture) of such gases. The nitrogen source gas can include ammonia.

Since the trapping layer pattern 30 is formed using the silicon source gas and the nitrogen source gas by the CVD process or the ALD process, the number of silicon-silicon bonds in the trapping layer pattern 30 can be relatively large. Thus, the resulting trap density of the trapping layer pattern 30 can be substantially larger than that of the upper portion 22 of the barrier layer pattern 20.

When the thickness of the trapping layer pattern 30 is less than about 10 Å, the number of trapping locations in the trapping layer is relatively small. Thus, in this case, carriers may not be efficiently trapped in the trapping locations. On the other hand, when the thickness of the trapping layer pattern 30 is greater than about 200 Å, this can cause the operation voltage required for operating the non-volatile memory device 1000 to increase. Thus, the thickness of the trapping layer pattern 30 is preferably in a range of about 10 Å to about 200 Å.

The blocking layer pattern 40 is provided on the trapping layer pattern 30. The gate electrode layer pattern 50 is provided on the blocking layer pattern 40. The blocking layer pattern 40 comprises, for example, a material having a relatively high dielectric constant. The gate electrode layer pattern 50 comprises, for example, a conductive material such as poly-silicon doped with impurities.

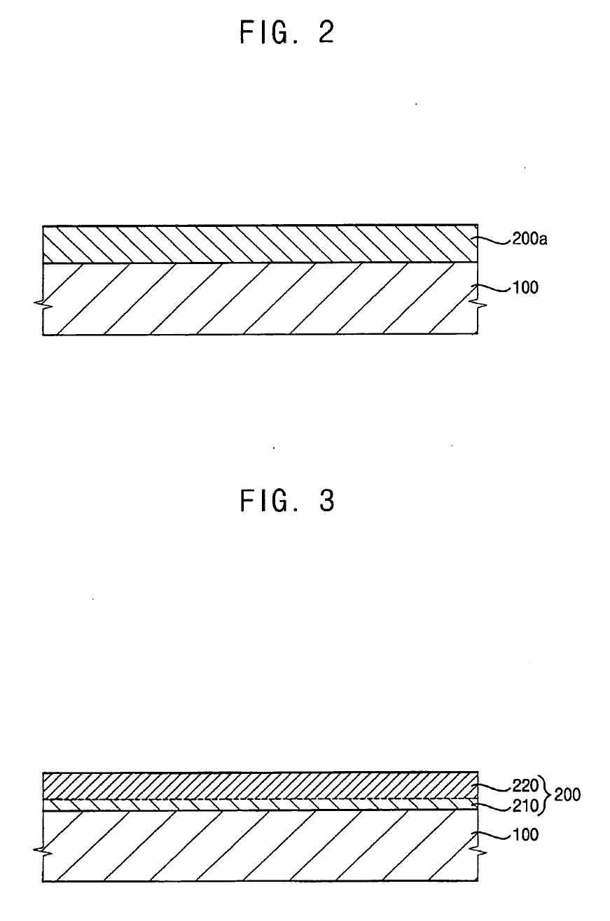

FIGS. 2 to 6 are cross-sectional views illustrating methods for manufacturing the non-volatile memory device of FIG. 1.

Referring to FIG. 2, an oxide layer 200a is formed on a substrate 100. The oxide layer 200a is formed, for example, by a thermal oxidation process, a CVD process or a radical oxidation process.

The oxide layer 200a is formed into a barrier layer 200 (See FIG. 3, below) for the device by subsequent processes. The barrier layer 200 includes a lower portion 210 and an upper portion 220. The lower portion 210 and the upper portion 220 comprise, for example, silicon oxide and silicon nitride, respectively. The lower portion 210 and the upper portion 220 are operative as energy barriers.

The data retention capacity of the non-volatile memory device 1000 generally depends on the respective reliabilities of the lower portion 210 and the upper portion 220 of the barrier layer 200. Therefore, characteristics of the lower portion 210 and the upper portion 220 may determine the maximum number of times that a programming step and an erasing step can be repeated in the resulting device.

It is typically required that the non-volatile memory device 1000 can reliably repeat the programming and erasing steps over about 1 million times. Accordingly, it is desired that the original oxide layer 200a, that is subsequently formed into the barrier layer 200 including the lower portion 210 and the upper portion 220, is formed using a radical oxidation process performed at a temperature above about 800° C. at a relatively low pressure below about 1 Torr in an atmosphere containing oxygen (O₂), hydrogen (H₂) and nitrogen (N₂). This is because such a radical oxidation process results in an oxide layer 200a that is relatively dense. In addition, when the oxide layer 200a is formed using radical oxidation process, the resulting thickness of the oxide layer 200a can be efficiently controlled.

When the thickness of the oxide layer 200a is less than about 25 Å, the oxide layer 200a is relatively thin so that the barrier layer 200 will not efficiently serve as an energy barrier. On the other hand, when the thickness of the oxide layer 200a is greater than about 250 Å, the oxide layer 200a is relatively thick, which can cause the operation voltage of the non-volatile device to increase. Thus, the thickness of the oxide layer 200a is preferably in a range of about 25 Å to about 250 Å.

Referring to FIG. 3, a radical nitridation process is performed on an upper portion of the oxide layer 200a so that the barrier layer 200 including the lower portion 210 including silicon oxide and the upper portion 220 including silicon nitride can be formed.

An example of a method of manufacturing a conventional non-volatile memory device is disclosed in Japanese Patent Laid-open Publication No. 2002-203917. In the disclosed conventional method, a first nitride layer is formed on a tunnel oxide layer using tetrachlorosilane (TCS: SiCl₄) by a CVD process. However, in such a case where the first nitride layer is formed on the tunnel oxide layer using the CVD process, an interface can present between the nitride layer and the tunnel oxide layer. Thus, carriers can become trapped at the interface. In addition, energy levels of the carriers can decrease when penetrating through the interface.

Furthermore, in the conventional approach where the first nitride layer is formed on the tunnel oxide layer by the CVD process, it can be difficult to efficiently control the resulting thickness of the first nitride layer. Thus, the resulting thickness uniformity of the first nitride layer can be lowered.

In addition, in the conventional approach where the first nitride layer is formed on the tunnel oxide layer by the CVD process, the resulting first nitride layer is relatively low in density. Thus, the trap density of the first nitride layer can be relatively high.

In contrast, in embodiments of the present invention, the barrier layer 200 having the lower portion 210 including silicon oxide and the upper portion 220 including silicon nitride is formed by performing a radical nitridation process on the upper portion of the oxide layer 200a.

Particularly, the radical nitridation process used for forming the barrier layer 200 can employ a reaction gas including ammonia (NH₃). The reaction gas can include nitrogen (N₂). In addition, the reaction gas can further include tetrachlorosilane, dichlorosilane (DCS: SiH₂Cl₂), or combinations (or mixtures) of such gases.

When the barrier layer 200 is formed by the radical nitridation process, no interface is present between the lower portion 210 and the upper portion 220 of the barrier layer 200. Thus, carriers will not become trapped between the lower portion 210 and the upper portion 220 of the barrier layer. In addition, energy levels of carriers will not decrease during transfer between the lower portion 210 and the upper portion 220 of the barrier layer 200.

In addition, when the barrier layer 200 is formed by the radical nitridation process, in accordance with the present invention, the thickness of the upper portion 220 can be efficiently controlled. Thus, thickness uniformity of the upper portion 220 can be relatively high.

Furthermore, when the barrier layer 200 is formed by the radical nitridation process, in accordance with the present invention, the upper portion 220 is relatively dense so that the number of resulting silicon-silicon bonds in the upper portion 220 can be relatively small. Thus, the resulting trap density of the upper portion 220 can be relatively low.

When the thickness of the upper portion 220 is less than about 10 Å, the upper portion 220 cannot efficiently serve as an energy barrier. On the other hand, when the thickness of the upper portion 220 is greater than about 200 Å, the resulting operation voltage of the non-volatile memory device 1000 can be relatively high. Thus, the thickness of the upper portion 220 is preferably in a range of about 10 Å to about 200 Å.

When a thickness of the lower portion 210 is less than about 15 Å, the lower portion 210 may not be efficiently used as an energy barrier. On the other hand, when the thickness of the lower portion 210 is greater than about 50 Å, the resulting operation voltage of the non-volatile memory device 1000 can be relatively high. Thus, the thickness of the lower portion 210 is preferably in a range of about 15 Å to about 50 Å.

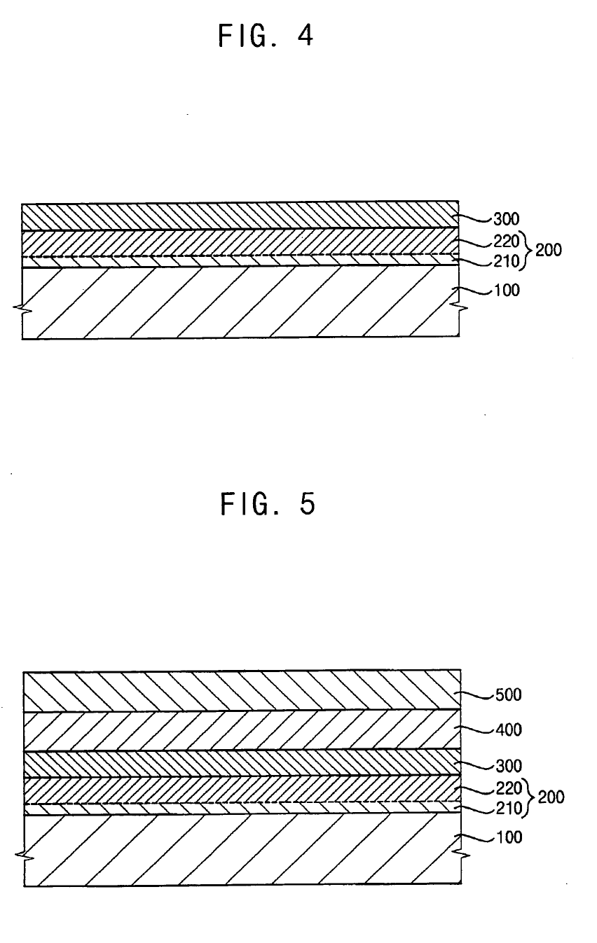

Referring to FIG. 4, a trapping layer 300 including silicon nitride is formed on the barrier layer 200.

In the conventional method disclosed in Japanese Patent Laid-Open Publication No. 2002-203917, a second nitride layer is formed on the first nitride layer using dichlorosilane by a CVD process. The adhesion coefficient of dichlorosilane is relatively large so that step coverage of the dichlorosilane can be relatively poor. Thus, when the second nitride layer is formed on the first nitride layer using dichlorosilane, the thickness uniformity of the second nitride layer can be relatively low.

In addition, in the conventional case where the second nitride layer is formed on the first nitride layer using dichlorosilane, the second nitride layer is formed at a relatively high temperature of greater than about 700° C. so that the second nitride layer can be rapidly formed. Thus, it is difficult to efficiently control the resulting thickness of the second nitride layer.

In contrast, in some embodiments of the present invention, the trapping layer 300 is formed using a silicon source gas and a nitrogen source gas. Examples of the silicon source gas include hexachlorodisilane (HCS: Si₂Cl₆), trisilane (Si₃H₈), octachlorosilane (Si₃Cl₈), etc, a combination (or a mixture) of such gases. The nitrogen source gas comprises, for example, ammonia (NH₃). The trapping layer 300 can be formed, for example, by a CVD process or an ALD process.

The adhesion coefficient of the silicon source gas is relatively small so that the step coverage of the silicon source gas is suitable. Thus, when the trapping layer 300 is formed using the silicon source gas, a thickness uniformity of the trapping layer 300 can be relatively high.

In addition, when the trapping layer 300 is formed using the silicon source gas, the trapping layer 300 can be formed at a relatively low temperature of about 450° C. to about 650° C. so that the trapping layer 300 can be slowly formed. Thus, the thickness of the trapping layer 300 can be efficiently controlled.

Furthermore, the number of silicon-silicon bonds in the silicon source gas is relatively larger than that in dichlorosilane. In general, an increase in the number of silicon-silicon bonds results in an increased trap density. Thus, when the trapping layer 300 is formed using the silicon source gas, the resulting trap density of the trapping layer 300 can be relatively high.

In addition, the number of atoms of chlorine in hexachlorodisilane or octachlorotrisilane is larger than that in dichlorosilane. In general, chlorine can penetrate into an interface between the barrier layer 200 and the substrate 100 so that chlorine improves interface characteristics. Thus, when the trapping layer 300 is formed by using hexachlorodisilane or octachlorotrisilane, the interface characteristics are improved so that another interface can be efficiently formed in the channel region.

When the trapping layer 300 is formed at a temperature less than about 450° C., byproducts such as ammonium chloride (NH₄Cl) can be generated. On the other hand, when the trapping layer 300 is formed at a temperature greater than about 650° C., the trapping layer 300 is too rapidly formed, making it difficult to control the resulting thickness of the trapping layer 300. As a result, the trapping layer 300 is preferably formed at a temperature ranging from about 450° C. to about 650° C.

When the thickness of the trapping layer 300 is less than about 10 Å, the number of trapping locations in the trapping layer 300 is relatively small, and thus, carriers are not efficiently trapped in the trapping locations. On the other hand, when the thickness of the trapping layer 300 is greater than about 200 Å, this can cause the operation voltage of the non-volatile memory device 1000 to increase. Thus, the thickness of the trapping layer 400 is preferably in a range of about 10 Å to about 200 Å.

Referring to FIG. 5, a blocking layer 400 and a gate electrode layer 500 are subsequently formed on the trapping layer 300. The blocking layer 400 comprises a material having a relatively high dielectric constant. The gate electrode layer 500 comprises a conductive material such as polysilicon doped with impurities.

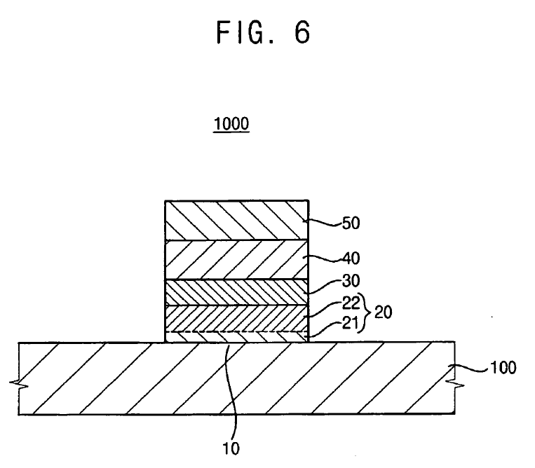

Referring to FIG. 6, the gate electrode layer 500, the blocking layer 400, the trapping layer 300 and the barrier layer 200 are subsequently patterned and etched so that a gate electrode layer pattern 50, a blocking layer pattern 40, a trapping layer pattern 30 and a barrier layer pattern 20 are formed. The barrier layer pattern 20 includes a lower portion 21 and an upper portion 22. Thus, the non-volatile memory device 1000 including the substrate 100, the barrier layer pattern 20, the trapping layer pattern 30, the blocking layer pattern 40 and the gate electrode layer pattern 50 is formed. A portion of the substrate 100 positioned under the barrier layer pattern 20 is used as the device channel region 10.

According to the present invention, a barrier layer pattern having an upper portion of silicon nitride and a lower portion of silicon oxide is formed by a radical nitridation process. As a result, there is no interface between the lower portion and the upper portion. In addition, the thickness of the upper portion may be efficiently controlled so that thickness uniformity of the upper portion is relatively high. Furthermore, the upper portion can be relatively dense, and the number of silicon-silicon bonds can be relatively small. Thus, the resulting trap density of the upper portion is relatively low.

Furthermore, a trapping layer including silicon nitride is formed on the barrier layer by using a silicon source gas including hexachlorodisilane, trisilane, octachlorotrisilane or a combination (or a mixture) thereof. Since the trapping layer is formed at a relatively low temperature, the trapping layer can be slowly formed and thus, the thickness of the trapping layer can be efficiently controlled. In addition, the trapping layer can have a relatively large trap density. Furthermore, characteristics of an interface between the barrier layer and the substrate are improved.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A non-volatile memory device comprising:
a substrate having a channel region;
a barrier layer pattern on the channel region of the substrate, the barrier layer pattern having an upper portion including silicon nitride and a lower portion including silicon oxide, the barrier layer pattern being formed by providing a silicon oxide layer on the substrate and performing a radical nitridation process on an upper portion of the silicon oxide layer;
a trapping layer pattern on the barrier layer pattern, the trapping layer pattern including silicon nitride;
a blocking layer pattern on the trapping layer pattern; and
a gate electrode layer pattern on the blocking layer pattern.

2. The non-volatile memory device of claim 1, wherein no interface is present between the upper portion and the lower portion of the barrier layer pattern.

3. The non-volatile memory device of claim 1 wherein the formation of the barrier layer pattern further comprises partially etching the silicon oxide layer after performing the radical nitridation process on the upper portion of the silicon oxide layer.

4. The non-volatile memory device of claim 1, wherein the radical nitridation process uses a reaction gas including ammonia.

5. The non-volatile memory device of claim 4, wherein the reaction gas further includes at least one material selected from the group consisting of tetrachlorosilane and dichlorosilane.

6. A method of manufacturing a non-volatile memory device, the method comprising:
forming a silicon oxide layer on a substrate;
forming a barrier layer by performing a radical nitridation process on an upper portion of the silicon oxide layer, the barrier layer having an upper portion including silicon nitride and a lower portion including silicon oxide;
forming a trapping layer on the barrier layer, the trapping layer including silicon nitride;
forming a blocking layer on the trapping layer;
forming a gate electrode layer on the blocking layer; and
partially etching the gate electrode layer, the blocking layer, the trapping layer and the barrier layer.

7. The method of claim 6, further comprising partially etching the upper portion of the barrier layer before forming the trapping layer.

8. The method of claim 6, wherein no interface is present between the upper portion and the lower portion of the barrier layer.

9. The method of claim 6, wherein the silicon oxide layer is formed on the substrate by a radical oxidation process.

10. The method of claim 6, wherein the radical nitridation process uses a reaction gas including ammonia.

11. The method of claim 10, wherein the reaction gas further includes at least one material selected from the group consisting of tetrachlorosilane and dichlorosilane.

12. The method of claim 6, wherein the trapping layer is formed on the barrier layer by using a reaction gas including at least one material selected from the group consisting of hexachlorodisilane, trisilane and octachlorotrisilane.

13. The method of claim 6, wherein the trapping layer is formed on the barrier layer at a temperature of about 450° C. to about 650° C.
